(19) United States
(12) Patent Application Publication
(10) Pub. No.: US 2005/0104984 A1
(43) Pub. Date: May 19, 2005

(54) Solid-state image sensing device and control method therefor

(75) Inventor: Yoshihiro Okada, Hashima-Shi (JP)

Correspondence Address: HOGAN & HARTSON L.L.P., 500 S. GRAND AVENUE, SUITE 1900, LOS ANGELES, CA, 90071-2611, US

(73) Assignee: SANYO ELECTRIC CO., LTD.

(21) Appl. No.: 10/988,092

(22) Filed: Nov. 12, 2004

(30) Foreign Application Priority Data
Nov. 14, 2003 (JP) 2003-385968

(51) Int. Cl. H04N 5/335

(52) U.S. Cl. 348/294

(57) ABSTRACT

A solid-state image sensing device includes an image capture section which takes external light rays and generates information charge, and a storage section, which is shielded from external light rays, and contains a plurality of transfer electrodes arranged on a surface of a semiconductor substrate. The solid-state image sensing device transfers information charge by using the transfer electrodes. This solid-state image sensing device adopts diodes formed and buried beneath the vicinity of the transfer electrodes, as a result of which it has become possible to suppress the occurrence of dark current without decreasing the sensitivity and saturation power of the image sensor.

### CROSS-REFERENCE TO RELATED APPLICATIONS

The disclosure of Japanese Patent Application No. 2003-385968 including specifications, claims, drawings and abstract is incorporated herein by reference in its entirety.

### BACKGROUND OF THE INVENTION

1. Field of the Invention

The present invention relates to a solid-state image sensing device for reducing noise of electric charge, and a method for controlling the solid-state image sensing device.

2. Description of the Related Art

The CCD (Charge Coupled Device) is an electric charge transfer device capable of transferring signal packets of information charge (electric charge) in good order in one direction at a speed synchronized with external clock pulses.

The frame-transfer-type-CCD solid-state image sensing device includes an image capture section 2i, a storage section 2s, a horizontal transfer section 2h, and an output section 2d as shown in FIG. 11. The image capture section 2i includes a plurality of vertical shift registers extending in parallel with each other in the vertical direction (vertical in the plane of FIG. 11), and the bits of the shift registers are arranged in a two-dimensional matrix. The storage section 2s includes a plurality of shift registers extending in parallel with each other in the vertical direction (vertical in the plane of FIG. 11). The vertical shift registers of the storage section 2s are shielded from light, and the bits of the shift registers function as storage pixels to store information charge (electric charge). The horizontal transfer section 2h is formed by a horizontal shift register arranged to extend in the horizontal direction (in the transverse direction in the plane of FIG. 11), and outputs of the registers of the storage section 2s are coupled to the bits of the horizontal shift register. The output section 2d is formed by including a capacitance for temporarily storing the electric charge transferred from the horizontal shift register of the horizontal transfer section 2h, and also including a reset transistor for ejecting the electric charge stored in the capacitance.

The light falling on the image capture section 2i generates information charges in the bits of the image capture section 2i. The information charges in a two-dimensional array on the image capture section 2i are transferred to the storage section 2s at high speed by the vertical shift registers of the image capture section 2i. Therefore, the information charges for one frame are stored in he vertical shift registers of the storage section 2s. After this, the information charges are transferred one line after another to the horizontal transfer section 2h. Then, the information charges are transferred in pixel units from the horizontal transfer section 2h to the output section 2d. The output section 2d converts the amount of charge per pixel into a voltage value, and changes in the voltage value are outputs of the CCD.

As shown in FIGS. 12A, 12B and 12C, the image capture section 2i and the storage section 2s are each made up of a plurality of shift registers formed on the surface portion of a semiconductor substrate 9. FIG. 12A is a schematic plan view showing a part of the conventional image capture section 2i, and FIGS. 12B and 12C are sectional side views taken along line A-A and line B-B.

A P-well (PW) 11 is formed in the N-type semiconductor substrate, and an N-well 12 is formed on top of the P-well 11. In other words, a P-well 11 added with P-type impurities is formed in an N-type semiconductor substrate 9. An N-well 12 with high concentration of N-type impurities is formed in the surface portion of the P-well 11. This surface portion indicates a portion that is shallow from the surface.

Separation regions 14 are provided to separate the channel regions of the vertical shift registers. The separation regions 14 formed by P-impurity-doped regions are formed in the N-well by ion implantation of P-type impurity ions arranged mutually in parallel at predetermined intervals. The N-well 12 is electrically partitioned by the adjacent separation regions 14. The spaces placed between the separation regions 14 are channel regions 22, which serve as transfer paths for information charges. Between the adjacent channel regions, the separation regions 14 build up potential barriers to thereby electrically isolate the channel regions 22.

An insulation film 13 is deposited on the surface of the semiconductor substrate 9. A plurality of transfer electrodes 24 made of a polysilicon film are arranged mutually in parallel so as to be at right angles with the extending direction of the channel regions 22 through the intermediary of this insulation film 13. To reduce the resistive components of the transfer electrodes 24, back wires 15 made of tungsten silicide which are connected through openings provided in the same pattern for every certain number of transfer electrodes, are provided in parallel in the extending direction of the channel regions 22. A set of three adjacent transfer electrodes 24-1, 24-2, and 24-3 corresponds to one pixel.

FIG. 13 shows the potential profile in the N-well 12, measured along the channel region 22 when caputuring images. When capturing images, by turning on the transfer electrodes 24-2, one of each set of the transfer electrodes 24, potential wells 50 are formed under the transfer electrodes 24-2, and by turning off the remaining transfer electrodes 24-1 and 24-2, information charge is stored in the potential wells 50 under the ON transfer electrodes. When transferring images, three-phase transfer clocks φ1˜φ43 are applied to each set of the adjacent three transfer electrodes 24-1, 24-2 and 24-3, for example, as a result of which the potentials of the channel regions 22 under the transfer electrodes 24-1, 24-2 and 24-3 are controlled so that information charge is transferred.

As described above, in a conventional solid-state image sensing device, after information charge is transferred from the image capture section 2i to the storage section 2s, the information charge is output to the output section 2d one line after another by the horizontal transfer section 2h formed continuously with the storage section 2s.

However, in a solid-state image sensing device mounted on an instrument with a function other than capturing images, such as a mobile phone, when using this other function, that is, when talking on the phone, for example, it sometimes happens that the transfer of information charge from the storage section 2s to the horizontal transfer section 2h must be interrupted. While output is interrupted, it is necessary to keep turned on at least one of the transfer electrodes 24-1 to 24-3 of the storage section 2s, and hold information charge in the related potential wells 50. Under the condition that some electrodes are kept turned on, a dark current occurs due to the effect of an interface state resulting from a defect existing at the interface between the insulation film 13 and the semiconductor substrate 9. The dark current caused by this defect-induced interface state is present as noise superimposed on the information charge held in the potential wells 50, and deteriorates the images taken by the CCD solid-state image sensing device.

### SUMMARY OF THE INVENTION

According to the present invention, a solid-state image sensing device, formed on a semiconductor substrate, includes an image capture section for capturing external light rays and generating information charge (electric charge); and a storage section shielded from incident external light rays and having a plurality of transfer electrodes arranged on a surface of the semiconductor substrate, the storage section being used to transfer the information charges by using the transfer electrodes, the solid-state image sensing device comprising:
a plurality of diodes formed and buried beneath the vicinity of corresponding transfer electrodes.

According to the present invention, a solid-state image sensing device formed on a semiconductor substrate includes an image capture section for capturing external light rays and generating information charges; a storage section, having a plurality of channel regions arranged mutually in parallel at predetermined intervals on a surface portion of the semiconductor substrate, the surface portion of each of the channel regions being of one electric conductive type and a plurality of transfer electrodes, for transferring the information charges by using the plurality of transfer electrodes, the plurality of transfer electrodes being arranged mutually in parallel in a direction intersecting the plurality of channel regions on a surface of the semiconductor substrate, the solid-state image sensing device comprising;
a plurality of diodes formed and buried beneath the vicinity of corresponding transfer electrodes, the surface portion of each of the diodes being of an electric conductive type opposite to the electric conductive type of the channel regions.

According to the present invention, there is provided a method of controlling a solid-state image sensing device, which includes an image capture section for capturing external light rays and generating information charges; and a storage section formed on a semiconductor substrate and shielded from incident external light rays, and including a plurality of transfer electrodes arranged on a surface of the semiconductor substrate, a plurality of diodes formed and buried beneath the vicinity of the transfer electrodes, and this controlling method comprises a first process of storing the information charges in the diodes under the condition that the transfer electrodes are all turned off.

### BRIEF DESCRIPTION OF THE DRAWINGS

FIG. 1 is a diagram showing a plan view of the storage section of a solid-state image sensing device according to a first embodiment of the present invention;

FIG. 2 is a diagram showing a side sectional view of the storage section of the solid-state image sensing device according to the first embodiment of the present invention;

FIG. 3-w of the storage section of the solid-state image sensing device according to the second embodiment of the present invention;

FIG. 5 is a diagram showing a timing chart in a method for controlling the solid-state image sensing device;

FIG. 6 is a diagram showing a potential distribution of the storage section of the solid-state image sensing device;

FIG. 7 is a diagram showing a potential distribution of the storage section of the solid-state image sensing device;

FIG. 8 is a diagram showing a potential distribution of the storage section of the solid-state image sensing device when charges were transferred;

FIG. 9 is a diagram showing a potential distribution of the storage section of the solid-state image sensing device when the charge transfer was interrupted;

FIG. 10 is a diagram showing a potential distribution of the storage section of the solid-state image sensing device when the charge transfer was resumed;

FIG. 11 is a conceptual diagram showing the structure of the solid-state image sensing device;

FIG. 12A is a plan view diagram showing the structure of the solid-state image sensing device as background technology;

FIGS. 12B and 12C are side sectional view diagrams showing the structure of the solid-state image sensing device as the background technology; and

FIG. 13 is a diagram for explaining how charges are stored in the solid-state image sensing device as the background technology.

### DESCRIPTION OF THE PREFERRED EMBODIMENTS

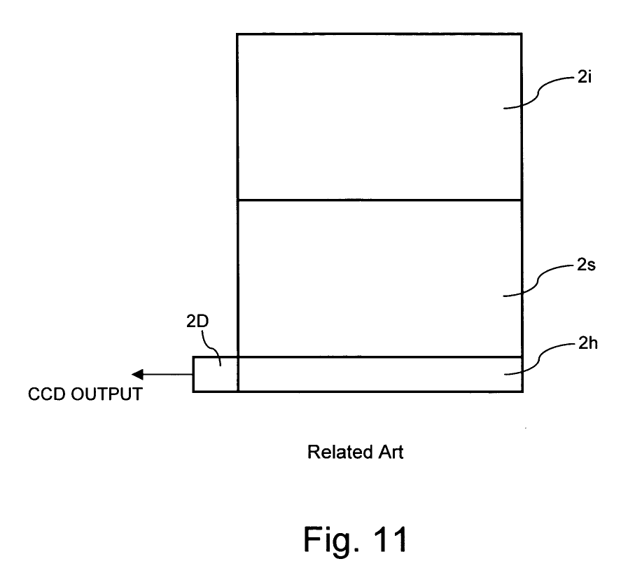

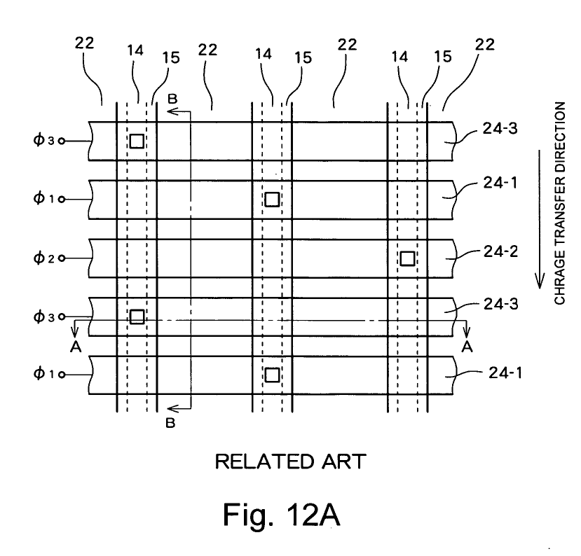

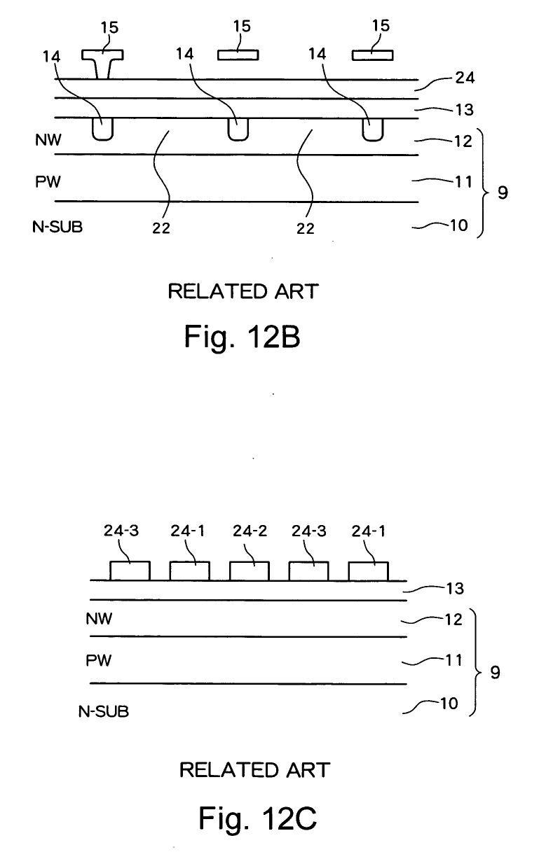

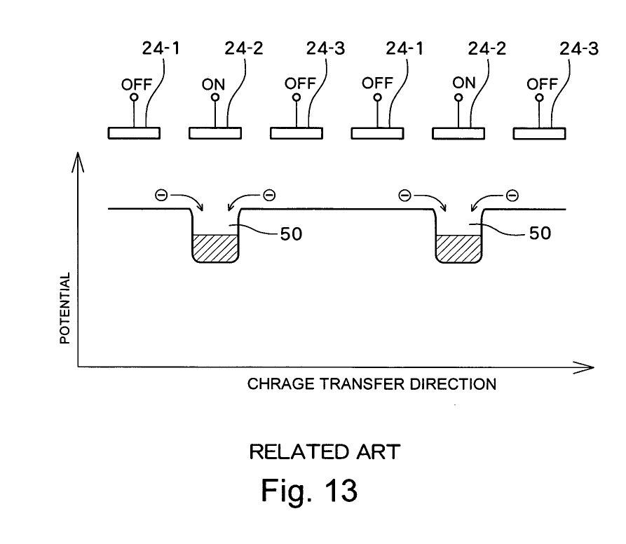

As in the solid-state image sensing device in the background technology in FIG. 11, the CCD solid-state image sensing device according a first embodiment of the present invention is formed including an image capture section 2i, a storage section 2s, a horizontal transfer section 2h, and an output section 2d. The CCD solid-state image sensing device according to this embodiment includes a feature different from before in the storage section 2s. Therefore, the following description will be limited to the storage section 2s.

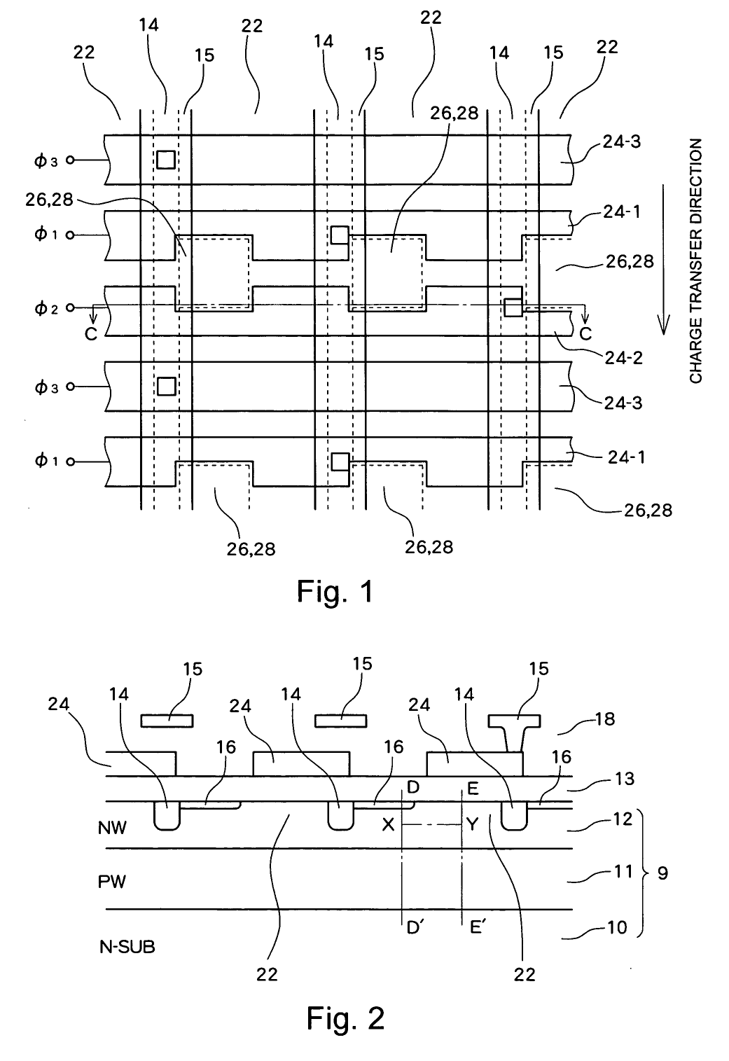

FIG. 1 is a schematic plan view showing part of the storage section 2s of the solid-state image sensing device according to the present invention. FIG. 2 is a side sectional view taken along line C-C in FIG. 1. Note that those parts which are the same as in the conventional structure are designated by the same reference numerals, and their descriptions are omitted.

As shown in FIGS. 1 and 2, the storage section 2s in the first embodiment of the present invention includes a plurality of shift registers formed on the surface portion of the semiconductor substrate.

The storage section 2s is formed on the surface portion of an N-type semiconductor substrate 9. The surface portion indicates a portion shallow from the surface. For the semiconductor substrate 9, a common semiconductor material, such as a silicon substrate added with N-type impurities, such as arsenic (As), phosphorus (P), or antimony (Sb), may be used. A suitable material for the semiconductor substrate 9 is a silicon substrate with doping concentration of not less than 1×10¹⁴/cm³ and not more than 1×10¹⁵/cm³.

A P-well (PW) 11, added with P-type impurities, is formed in the N-type semiconductor substrate 9. As the P-type impurities, boron (B), aluminum (Al), gallium (Ga) or indium (In) may be used. The doping concentration for the P-well is desirably higher than the doping concentration of the semiconductor substrate 9 and a preferable value of the P-well doping concentration is not less than 5×10¹⁴/cm³ and not more than 5×10¹⁶/cm³. An N-well (NW) 12 added with N-type impurities at a high concentration formed at the surface portion of the P-well 11. The doping concentration of the N-well 12 is desirably higher than the doping concentration of the P-well and a preferable value of the N-well doping concentration is not less than 1×10¹⁶/cm³ and not more than 1×10¹⁷/cm³. In the N-well, separation regions 14 are formed, which are made up of P-type impurity regions added with a high concentration of P-type impurities and arranged in parallel mutually spaced apart by a specified amount. The doping concentration of the separation regions 14 is preferably not less than 1×10¹⁶/cm³ and not more than 5×10¹⁷/cm³. The separation regions 14 build potential barriers in the adjacent channel regions 22 to electrically isolate the channel regions from one another.

An insulation film 13 is deposited on the surface of the semiconductor substrate 9. The insulation film 13 may be formed by an insulation material used in semiconductor integrated devices, such as a silicon oxide film (SiO₂), a silicon nitride film (SiN), etc.

A plurality of transfer electrodes 24 are arranged mutually in parallel so as to be at right angles with the extending direction of the separation regions 14 with interposition of the insulation film 13. The transfer electrodes 24 may be formed by a polysilicon film, a metal film, or a combination of these materials. According to this embodiment, a set of three adjacent transfer electrodes 24-1, 24-2 and 24-3 corresponds to one pixel.

P⁺ regions 16 added with a high concentration of P-type impurities are formed in the regions of N-wells 12 placed between the adjacent separation regions 14. Each PN junction between the P⁺ region 16 and the N-well 12 forms a diode 26. At least one diode is provided to each set of three transfer electrodes 24-1, 24-2 and 24-3, which correspond to one pixel.

Through openings formed by notch regions 28 of the adjacent transfer electrodes 24, ions of P-type impurities are implanted into the surface of the N-well, by which high-density P⁺-type regions 16 are formed on the surface of the semiconductor substrate 9. At this time, the shape of the high-density P⁺-type regions is decided in such a way that the transfer electrode 24 is not cut off in the middle of each transfer electrode 24.

By adding P-type impurities to the surface portion through the openings of the notch regions by using the transfer electrodes as the mask, the P⁺ regions 16 can be formed. In this process, P-type impurities, boron ions for example, are implanted at an acceleration voltage of 20 keV and under an implantation condition of 1×10¹²/cm². The doping concentration of the P⁺-type regions 16 is preferably not less than 1×10¹⁶/cm³ and not more than 5×10¹⁷/cm³.

The diodes 26 may be formed beneath the vicinity of the transfer electrodes 24 without providing the notch regions 28.

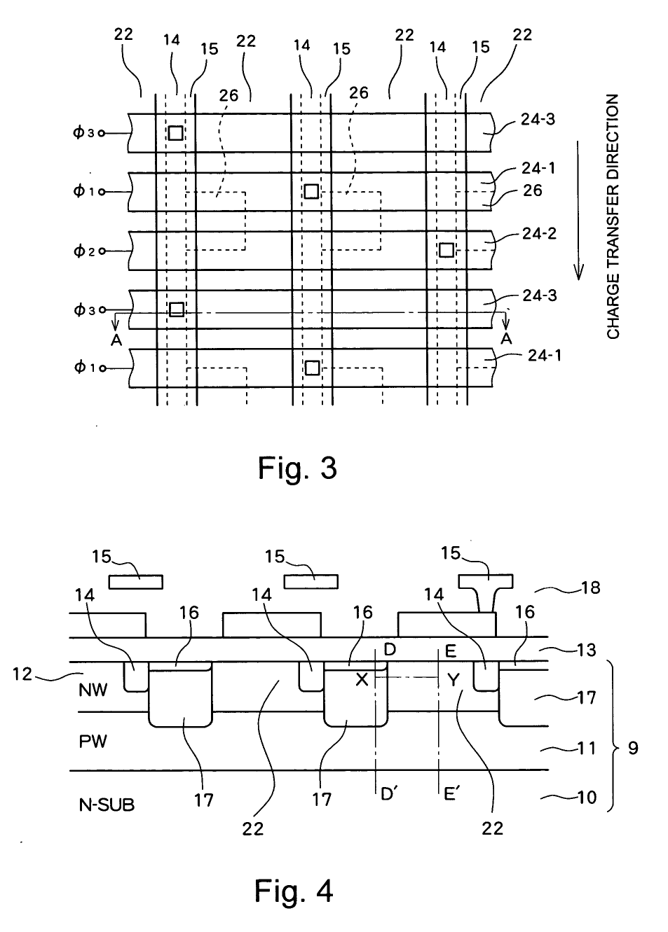

For example, in FIG. 1, the notch regions 28 were provided for the respective transfer electrodes 24, but the diodes 26 were formed with the notch regions 28 used as the mask. However, a resist mask may be formed by photolithographic technology, for example, by which the diodes 26 may be formed. If a resist is used as a mask, the notch regions 28 need not be provided in the transfer electrodes 24, but as shown in FIG. 3, it is only necessary to form at least one diode for each set of transfer electrodes 24, which define one pixel.

As shown in the side sectional view drawing of FIG. 4, through the transfer electrodes 24 used as the mask, P-type and N-type impurities may be injected into the surface portions of the openings at the notch regions 28 by ion implantation to form the P⁺-type regions 16 and the N⁺-type regions 17.

Through the openings shown in FIG. 1 formed as a result of forming the notch regions 28, ions of N-type impurities are injected in such a manner that they spread along the depth direction of the P-well 11 and the N-well 12. In this manner, the N⁺-type regions are formed. The doping concentration of the N⁺-type regions 17 is desirably higher than the doping concentration of the N-well and a preferable value of the N⁺-type-region doping concentration is not less than 1×10¹⁶/cm³ and not more than 5×10¹⁷/cm³. By implanting a high concentration of P-type impurities into the surface region of the N-well 17, high-density P⁺-type regions 16 are formed in the surface layer of the substrate. The doping concentration of the P⁺-type regions 16 is desirably higher than the doping concentration of the N⁺-type regions 17 and a preferable value of the P⁺-type-region doping concentration is not less than 1×10¹⁶/cm³ and not more than 5×10¹⁷/cm³.

The P⁺-type regions 16 and the N⁺-type regions 17 may be formed beneath the vicinity of the transfer electrodes 24 by using a resist mask without providing the notch regions 28 as shown in FIG. 3, and then buried-type diodes 26 may be formed.

The P⁺-type regions 16, used to form diodes 26, are preferably formed to contact the separation regions 14 as shown in FIG. 4. As a result, the separation regions 14 and the P⁺-type regions 16 can always be kept at the same potential. Because the separation regions 14, which are independent of the transfer electrodes 24, are always kept at a fixed potential, the inside of the P⁺-type regions 16 and the inside of the channel regions 22 can be controlled so that they are at different potential levels.

The CCD solid-state image sensing device takes incident light rays and generates information charges according to the intensity of the external light rays by photoelectric conversion. The diodes 26 are used to store information charges from the image capture section 2i for their corresponding pixels.

Of the regions placed between the separation regions 14, the regions where diodes 26 are not formed serve as the channel regions 22 to transfer the information charges. Each channel region 22 is electrically isolated by the separation regions 14.

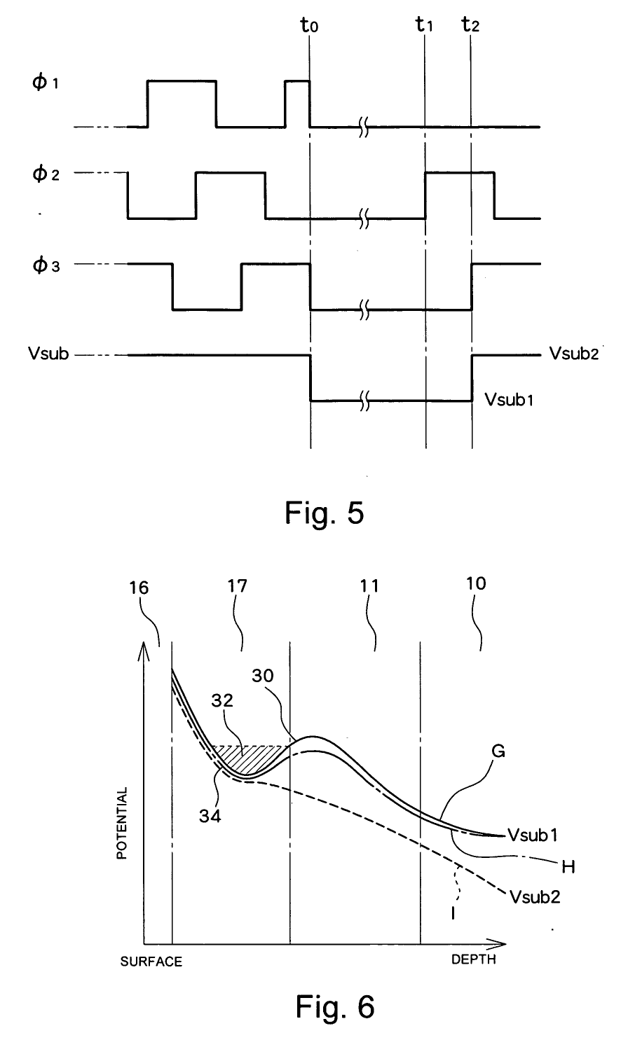

Description will next be given of a method for controlling the CCD in this embodiment of the present invention. FIG. 5 shows a timing chart when the charges were transferred, when the transfer was interrupted, and when the transfer was started. The clock pulses φ1˜φ3 were respectively applied to the transfer electrodes 24-1˜24-3. A substrate potential V_{sub} was applied to the N-type substrate 10.

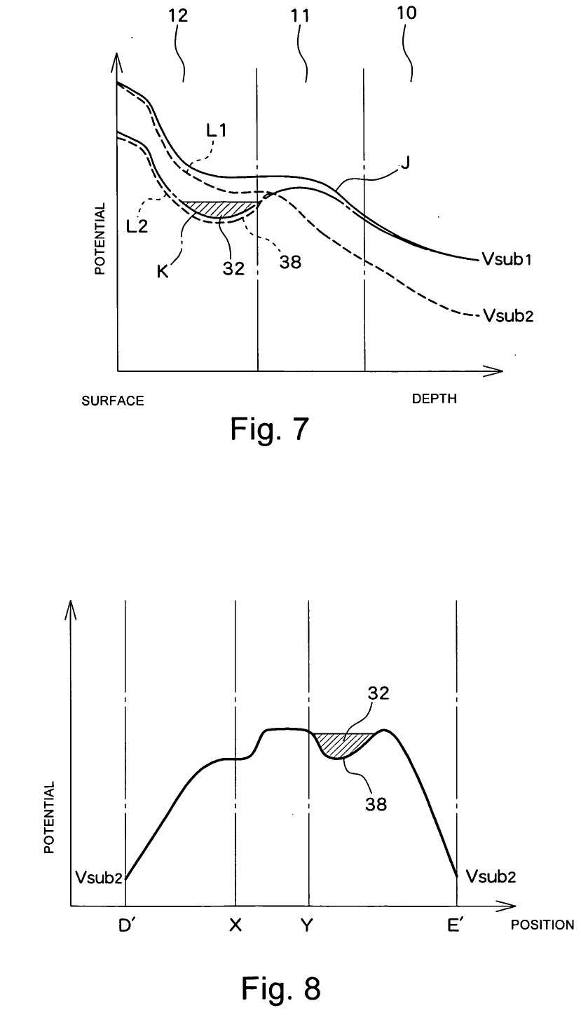

FIGS. 6 and 7 show potential distributions in the depth direction, measured along line D-D′ and line E-E′ in FIG. 4 in respective time periods when charges were transferred, when the transfer was interrupted, and when the transfer was started. The horizontal axis indicates the depths measured from the surface of the semiconductor substrate 9, and the vertical axis indicates potentials at different positions. The upper area denotes the positive potential side, and the lower area denotes the negative potential side.

Before time t0, the information charges were transferred vertically along the channel regions 22. As shown in FIG. 5, clock pulses φ1˜φ3, which were out of phase with each other, were applied to the transfer electrodes 24-1, 24-2 and 24-3. At the same time, a positive potential was applied to the N-type substrate 10. At this time, the potential distribution along the line D-D′ is as indicated by line I of FIG. 6, and the potential gradually decreased from the P⁺-region towards the N-type substrate 10. As a result, a potential well was not formed in the P⁺-type region 16. The potential distribution along line E-E′ contiguous to the transfer electrode 24, to which a negative potential was applied, is as indicated by line L1 of FIG. 7; namely, the potential gradually decreased from the N-well towards the N-type substrate 10. Consequently, a potential well was not formed in the N-well 12. On the other hand, the potential distribution measured along line E-E′ contagious to the transfer electrode 24, to which a positive potential was applied, is as indicated by line L2 of FIG. 7; namely, the potential gradually deceased where the L2 approaches the deep section of the N-well, came to have a minimum value in the N-well 12, rose again while moving towards the P-well 11, had a maximum value in the P-well 11, and decreased again where the line L2 approaches the N-type substrate 10. Accordingly, a potential well 38 was formed in the N-well 12.

FIG. 8 shows a potential distribution measured along line D′-X-Y-E′ (shown in FIG. 4) located in the vicinity of the transfer electrode to which a positive potential was applied. In FIG. 8, the horizontal axis indicates positions along line D′-X-Y-E′, and the vertical axis indicates potentials. As indicated by line I in FIG. 6 and by line L2 in FIG. 7, a potential well was not formed in the region of the diode 26.

Meanwhile, information charge 32 was stored in the potential well 38 formed in the N-well 12. Clock pulses φ1˜φ3 were sequentially applied to the transfer electrodes 24-1˜24-3, and the potential wells 38 formed under the transfer electrodes 24-1˜24-3 moved in the extending direction of the channel regions 22. Accordingly, the information charges 32 were transferred sequentially.

At times t0˜t1, the transfer of information charges 32 at the storage 2s was interrupted. In this process, a negative potential was applied to each of the transfer electrodes 24-1˜24-3, and a negative potential was also applied to the N-type substrate 10. For this reason, the potential distribution along line D-D′ was as indicated by line G in FIG. 6. The potential gradually decreased from the P⁺-type region 16, became a minimum value in the N⁺-type region 17, rose again where the line G approaches the P-well, had a maximum value in the P-well, and decreased again where the line G approaches the N-type substrate 10. In consequence, a potential well 30 was formed in the N⁺-type region 16. Meanwhile, the potential distribution along line E-E′ is as indicated by line J in FIG. 7, and the potential gradually decreased where the line J moves away from the N-well 12 and approaches the deep section of the N-type substrate 10. Thus, in the region along line E-E′, a potential well was not formed or only a very shallow potential well was formed.

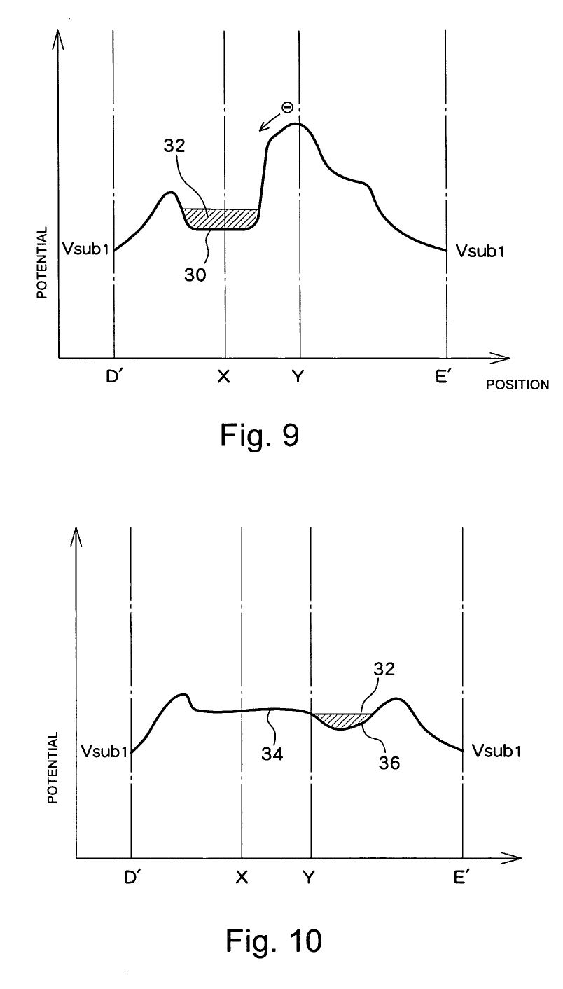

FIG. 9 shows a potential distribution measured along line D′-X-Y-E′ shown in FIG. 4 when the transfer of charges was interrupted. In FIG. 9, the horizontal axis indicates positions along the line D′-X-Y-E′, and the vertical axis indicates potentials. As shown by the line G in FIG. 6 and the line J in FIG. 7, the potential well 30 was formed in the area of each diode 26 when the transfer of charges was interrupted. Therefore, the information charges 32 stored in the potential wells 38 in the channel regions 22 before charge transport were transferred to the potential wells 30 of the diodes 26.

During the interruption of charge transfer, by applying a negative potential to the transfer electrodes, the interface state between the P+-type region 16 and the N-well 12 or between the P⁺-type region and the N⁺-type region 17 is terminated by holes as shown in FIG. 5. As a result, the charges (electrons) that occur at the interface recombine with holes, a face which makes it possible to inhibit the occurrence of a dark current during the interruption of the charge transfer.

At times t1˜t2, the charge transfer that was interrupted is restarted. At this time, a positive potential is applied to either the transfer electrode 24-1 or the transfer electrode 24-2, which is adjacent to the electrode 26, and the N-type substrate 10 is kept at a negative potential. In the timing chart of FIG. 5, the clock pulse φ2 applied to the transfer electrode is set at positive potential. At this point in time, the potential distribution along the line D-D′ contiguous to the transfer electrode 24-2 is as indicated by line H in FIG. 6; in which the potential gradually decreased, became a minimum value in the N⁺-type region, increased again when the line H approached the P-well 11, had a maximum value in the P-well 11, and again decreased when the line H approached the N-type substrate 10. Consequently, a potential well 34 was formed in the P⁺-type region. On the other hand, a potential distribution along the line E-E′ contiguous to the transfer electrode 24-2 is as indicated by line K in FIG. 7, in which the potential gradually decreased as the line K approached the deep end of the N-well 12, became a minimum value in the N-well 12, increased again where the line K approaches the P-well 11, had a minimum value in the P-well 11, and again decreased where the line K moves towards the N-type substrate 10. In consequence, a potential well 36 deeper than the potential well 34 in the diode 26 was formed in the N-well 12.

FIG. 10 shows a potential distribution along the line D′-X-Y-E′ (shown in FIG. 4) when a pulse is applied to the gate to transfer the charges. In FIG. 10, the horizontal axis indicates positions along the D′-X-Y-E′ line, and the vertical axis indicates potentials. As indicated by the line H in FIG. 6 and the line K in FIG. 7, the potential well 34 formed in the diode 26 is shallow, whereas the potential well 36 formed in the channel region 22 is deep. During the interruption of charge transfer, the information charges stored in the potential well 30 formed in the diode 26 are transferred to the potential well 36 formed in the channel region 22.

After this, in the same manner as before the time t0, by applying clock pulses φ1˜φ3, which are out of phase, to the transfer electrodes 24-1˜24-3, the information charges can be transferred again in a direction towards the channel region 22.

As has been described, according to this embodiment, when the transfer of information charges is interrupted, the charges that occur due to the interface state can be decreased, and the effects of dark current on images can be suppressed. In other words, without sacrificing the sensitivity and the saturation power, noise resulting from the occurrence of the dark current can be reduced. Therefore, it becomes possible to improve the quality of images taken by means of the solid-state image sensing device.

The present invention is not limited to the embodiments described above, and various changes and modifications may be made without departing from the spirit or scope of the invention.

1. A solid-state image sensing device, formed on a semiconductor substrate, including an image capture section for capturing external light rays and generating information charges (electric charges); and a storage section shielded from incident external light rays and having a plurality of transfer electrodes arranged on a surface of said semiconductor substrate, said storage section being used to transfer the information charges by using the transfer electrodes, said solid-state image sensing device comprising:
a plurality of diodes formed and buried beneath the vicinity of corresponding the transfer electrodes.

2. A solid-state image sensing device formed on a semiconductor substrate including an image capture section for capturing external light rays and generating information charges; a storage section, having a plurality of channel regions arranged mutually in parallel at predetermined intervals on a surface portion of the semiconductor substrate, the surface portion of each of the channel regions being of one electric conductive type and a plurality of transfer electrodes, for transferring the information charges by using the plurality of transfer electrodes, the plurality of transfer electrodes being arranged mutually in parallel in a direction intersecting the plurality of channel regions on a surface of the semiconductor substrate, said solid-state image sensing device comprising:
a plurality of diodes formed and buried beneath the vicinity of corresponding transfer electrodes, the surface portion of each said diode being of an electric conductive type opposite to the electric conductive type of the channel regions.

3. The solid-state image sensing device according to claim 2, wherein an impurity concentration of the regions of one electric conductive type, where said diodes are formed, is higher than an impurity concentration of the channel regions of the one electric conductive type.

4. The solid-state image sensing device according to claim 2, comprising:
a plurality of separation regions, each being disposed between respective adjacent ones of the plurality of channel regions, the surface regions of the separation regions are of a electric conductive type opposite to the electric conductive type of the channel regions, wherein the regions, where the diodes are formed, are formed in the vicinity of the regions of the semiconductor substrate where the separation regions are formed.

5. The solid-state image sensing device according to claim 3, comprising:
a plurality of separation regions, each being disposed between respective adjacent ones of the plurality of channel regions, the surface regions of the separation regions are of a electric conductive type opposite to the electric conductive type of the channel regions, wherein the regions, where the diodes are formed, are formed in the vicinity of the regions of the semiconductor substrate where the separation regions are formed.

6. A method of controlling a solid-state image sensing device, including an image capture section for capturing external light rays and generating information charges; and a storage section formed on a semiconductor substrate and shielded from incident external light rays, and including a plurality of transfer electrodes arranged on a surface of the semiconductor substrate, a plurality of diodes formed and buried beneath the vicinity of the transfer electrodes, said controlling method comprising:
a first process of storing the information charges in the diodes under the condition that the transfer electrodes are all turned off.

7. The method for controlling the solid-state image sensing device according to claim 6, further comprising:
a second process for transferring the information charges, wherein a potential of the semiconductor substrate is a potential at which a potential well is not formed in the region where the diode is formed.

8. The method for controlling the solid-state image sensing device according to claim 7, wherein the potential of the semiconductor substrate is a potential which differs between the first process and the second process.
